(19) United States
(12) Patent Application Publication
(10) Pub. No.: US 2024/0329143 A1
(43) Pub. Date: Oct. 3, 2024

(54) FAULT MONITORING DEVICE FOR A POWER SYSTEM

(71) Applicant: Rolls-Royce Deutschland Ltd & Co KG, Blankenfelde-Mahlow (DE)

(72) Inventors: Máté BÉRCES, Albertisa (HU); Csaba BLEUER, Budapest (HU)

(21) Appl. No.: 18/605,362

(22) Filed: Mar. 14, 2024

(30) Foreign Application Priority Data
Mar. 30, 2023 (GB) 2304711.1

(51) Int. Cl. G01R 31/3835; G01R 31/36; G01R 31/389; H01M 10/48

(52) U.S. Cl. CPC G01R 31/3835; G01R 31/3644; G01R 31/389; H01M 10/48

(57) ABSTRACT

A fault monitoring device for a power system includes: a first parallel circuit of resistors that includes a first branch and a second branch both connected to a high side voltage rail of the power system; and a second parallel circuit of resistors that includes a third branch and a fourth branch both connected to a low side voltage rail of the power system. The second branch includes at least two electrical resistors arranged in series, wherein at least one electrical resistor may be short-circuited by a first switch. The fourth branch includes at least two electrical resistors arranged in series, wherein at least one electrical resistor may be short-circuited by a second switch. A controller is configured to selectively switch the switches to provide for different states of the circuits and determine resistance values for the high side and low side insulation resistances of the power system.

The present patent document claims the benefit of United Kingdom Patent Application No. 2304711.1, filed Mar. 30, 2023, which is hereby incorporated by reference in its entirety.

### TECHNICAL FIELD

The present disclosure relates to a fault monitoring device for a power system and a method for estimating the end voltage reached at the end of charging a capacitance.

### BACKGROUND

United States patent applications US 2022/0413034 A1 and US 2022/0413035 A1 disclose an insulation monitoring device that includes a primary resistance circuit and a secondary resistance circuit arranged in parallel to a high side insulation resistance and a low side insulation resistance, wherein the secondary resistance circuit includes additional resistors which are selectively connectable to a high voltage bus via a switching circuit. Four different states may be implemented by the switches. Voltage values associated with the different states are used to calculate the resistance values for the high side insulation resistance and the low side insulation resistance. The underlying idea lies in the injection of a common mode voltage on the high-voltage bus by connecting additional resistors of the secondary resistance circuit to the high voltage bus.

With such prior art insulation monitoring devices, an important design aspect is the maximum common mode voltage impressed onto the high voltage bus. A drawback lies in that the resistance of the additional resistors may need to be large in value (e.g., larger than 50 MΩ) in view of the fact that the high side insulation resistance and the low side insulation resistance may be high in value. Otherwise, no substantial common mode voltage may be injected to the high-voltage bus. However, implementing the additional resistors with a high resistance may be difficult in view of potential contaminations during manufacturing and operation.

Another drawback lies in that in case there is an insulation fault with the high side insulation resistance or the low side insulation resistance, the common mode voltage is very small, and the measurement accuracy is thus decreased.

A still further drawback lies in that long response times are required when measuring high side insulation resistances and low side insulation resistances with high resistance values due to the fact that RC circuits with capacitive loads are present in the system, wherein such RC circuits may have large RC time constants.

The present disclosure provides an insulation monitoring device and a method that addresses the above-mentioned drawbacks or at least provides a useful alternative to known insulation monitoring devices and methods.

### SUMMARY AND DESCRIPTION

The scope of the present disclosure is defined solely by the appended claims and is not affected to any degree by the statements within this summary. The present embodiments may obviate one or more of the drawbacks or limitations in the related art.

According to a first aspect, a fault monitoring device for a power system is provided. The power system for which the fault monitoring device is provided for is of the kind that includes a high side voltage rail, a low side voltage rail, and a chassis insulated by a high side insulation resistance from the high side voltage rail and insulated by a low side insulation resistance from the low side voltage rail. The high side voltage rail and the low side voltage rail form part of a high voltage bus connected to a DC battery.

The fault monitoring device includes a first parallel circuit of resistors and a second parallel circuit of resistors. The first parallel circuit of resistors includes a first branch and a second branch both connected at one end thereof to the high side voltage rail of the power system. The second parallel circuit of resistors includes a third branch and a fourth branch both connected at one end thereof to the low side voltage rail of the power system. It is further provided that the first branch, second branch, third branch, and fourth branch are each connected at the other end thereof to the chassis of the power system. The second branch of the first parallel circuit includes at least two electrical resistors arranged in series, wherein at least one of the electrical resistors may be short-circuited by a first switch. The fourth branch of the second parallel circuit also includes at least two electrical resistors arranged in series, wherein at least one of the electrical resistors may be short-circuited by a second switch.

The fault monitoring device further includes a controller configured to selectively switch the switches of the second branch and of the fourth branch to provide for different states of the first and second parallel circuits. The controller is further configured to determine from voltage changes associated with the different states the resistance values for the high side insulation resistance and for the low side insulation resistance of the power system.

Aspects of the disclosure are thus based on the idea of providing parallel resistor networks both on the high side and on the low side of a power system, wherein one of the branches of each resistor network includes resistors which may be short-circuited by switches, thereby allowing injection of a common mode voltage on the high-voltage bus. By using switches to short-circuit resistors, more current is allowed to flow compared to circuits as disclosed in US 2022/0413034 A1 and US 2022/0413035 A1, thereby increasing the impressed common mode voltage. At the same time, the maximum resistance of the branch with the resistors that may be short-circuited may be limited. Limitations in the common mode voltage impressed onto the high voltage bus and regarding the maximum resistance in the parallel resistor networks may thus be avoided.

According to an embodiment, the second branch of the first parallel circuit includes three electrical resistors arranged in series, wherein two of the electrical resistors may be short-circuited by the first switch and a third switch, respectively. In the same manner, the fourth branch of the second parallel circuit includes three electrical resistors arranged in series, wherein two of the electrical resistors may be short-circuited by the second switch and a fourth switch, respectively. By the provision of several switches a plurality of states may be realized, allowing additional options and granularity in the injection of a common mode voltage. Further, different measurement ranges may be defined. In an embodiment, a high measurement range is defined in case the quotient of the product to the sum of the high side insulation resistance and the low side insulation resistance is large in value, such as larger than a particular resistance value dependent on system parameters such as 2MΩ. A low measurement range is defined in case the quotient of the product to the sum of the high side insulation resistance and the low side insulation resistance is small in value, such as smaller than a particular resistance value dependent on system parameters such as 2MΩ. Different switches are switched depending on relevant measurement range.

In a further embodiment, the controller is configured to define two different states by the selective switching, wherein the controller determines from the voltage changes associated with the two different states the resistance values for the high side insulation resistance and the low side insulation resistance. Accordingly, two different states only need to be defined by the selective switching. Based on the corresponding voltage changes (and the corresponding common mode voltage injection on the high-voltage bus), the high side insulation resistance and the low side insulation resistance are determined.

To this end, in an embodiment, the controller is configured to determine from the voltage changes associated with the two different states the resistance values for the high side insulation resistance and the low side insulation resistance in that it is configured to: measure the high side voltage between the high side voltage rail and the chassis; measure the low side voltage between the chassis and the low side voltage rail; measure the high side voltage and the low side voltage in the two different states; and calculate the high side insulation resistance and the low side insulation resistance using the high side voltages of the two different states, the low side voltages of the two different states, and the change of resistance of the sum of the resistors of the second branch and/or of the sum of the resistors of the fourth branch between the two different states. The calculation is in accordance with Ohm's law and the well-known formulae about the total resistance in a series circuit and a parallel circuit of resistances.

In this respect, a first state may be defined in that one of the electrical resistors of the second branch is short-circuited while none of the electrical resistors of the fourth branch is short-circuited, and in that the second state is defined in that none of the electrical resistors of the second branch is short-circuited while one of the electrical resistors of the fourth branch is short-circuited. The corresponding bias leads to the injection of a common mode voltage.

More particularly, in case two switches are present both in the second branch and in the fourth branch, in the first state one of the electrical resistors of the second branch may be short-circuited by the first switch, and in the second state one of the electrical resistors of the fourth branch may be short-circuited by the second switch. Such a configuration may be used in the above-mentioned high measurement range.

Alternatively, in the first state one of the electrical resistors of the second branch may be short-circuited by the third switch, and in the second state one of the electrical resistors of the fourth branch may be short-circuited by the fourth switch. Such a configuration may be used in the above-mentioned low measurement range.

In a specific embodiment, the high side insulation resistance R_{ISOH} and the low side insulation resistance R_{ISOL} are calculated by the formulae:

$${R}_{{ISO}_{H}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}- \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \\ \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}} + \frac{1}{{R}_{{INJ}_{OFF}}} - \frac{1}{{R}_{{INJ}_{ON}}}\end{matrix}}$$

$${R}_{{ISO}_{L}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}\frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{OFF}}} - \frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{ON}}} - \\ \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}}\end{matrix}}$$

wherein: R_{ISOH} is the high side insulation resistance; R_{ISOL} is the low side insulation resistance; U_{HIGH1} is high side voltage between the high side voltage rail and the chassis in the first state; U_{HIGH2} is the high side voltage between the high side voltage rail and the chassis in the second state; U_{LOW1} is the low side voltage between the chassis and the low side voltage rail in the first state; U_{LOW2} is the low side voltage between the chassis and the low side voltage rail in the second state; R_{MEAS} is the resistance of the first branch and the resistance of the third branch (assuming these are identical); R_{INJON} is the resistance of the sum of the resistors of the second branch and the sum of the resistors of the fourth branch if one of the resistors of the respective branch is short-circuited (assuming these are identical for the second branch and for the fourth branch); and R_{INJOFF} is the resistance of the sum of the resistors of the second branch and the sum of the resistors of the fourth branch if none of the resistors are short-circuited (assuming these are identical for the second branch and for the fourth branch).

In an embodiment, the first branch includes a first voltage divider, wherein the fault monitoring device is configured to measure the high side voltage between the high side voltage rail and the chassis by the first voltage divider. Further, the third branch includes a second voltage divider, wherein the fault monitoring device is configured to measure the low side voltage between the low side voltage rail and the chassis by the second voltage divider. The use of a voltage divider represents a simple but effective means for measuring the high side voltage and the low side voltage.

The voltage changes associated with the different states settle with an exponential curve due to capacitances that are connected in parallel to the high side insulation resistance and the low side insulation resistance. Such capacitances represent the capacitance of the power system and may be formed, e.g., by cable insulations and filter capacitors.

In an embodiment, the controller is configured to apply a regression analysis that estimates the voltage change before they are settled in. The provision of such regression analysis allows to reduce the time it takes to determine the high side insulation resistance and the low side insulation resistance. This time depends on the resistance and capacitance values of RC circuits present in the system. Such RC circuit may have large RC time constants of up to tens of seconds when a high capacitive load and a high resistance are present, wherein the time constant is equal to the product of R and C (R*C). Without a regression analysis, the time of several time constants (e.g., at least five) needs to be waited until the high side insulation resistance and the low side insulation resistance may be determined, which means a long response time. Using a regression analysis, the settled in value may be calculated without having to wait for the voltage settling in.

In an embodiment, the controller is configured to apply a regression analysis for the voltage of each of the capacitances, wherein the regression analysis includes: measuring voltage values at the beginning only of an exponential charging curve charging the capacitance; calculating the derivatives of the measured voltage values and subsequently a logarithm of the derivatives; fitting a line through the calculated values using a linear regression method, the line being defined by parameters; and calculating the end voltage using the initial voltage value of the capacitance and the line parameters.

In a further aspect, a power system is provided that includes: a DC battery having a DC battery positive terminal, a DC battery negative terminal, and a battery voltage; a high side voltage rail connected to the DC battery positive terminal; a low side voltage rail connected to the DC battery negative terminal; a chassis; a high side insulation resistance insulating the chassis from the high side voltage rail; a low side insulation resistance insulating the chassis from the low side voltage rail; and a fault monitoring device as disclosed herein.

In a still further aspect, a method is disclosed for estimating the end voltage reached at the end of charging a capacitance. The method includes: measuring voltage values at the beginning only of an exponential charging curve charging the capacitance; calculating the derivatives of the measured voltage values and subsequently a logarithm of the derivatives; fitting a line through the calculated values using a linear regression method, the line being defined by parameters; and calculate the end voltage using the initial voltage value of the capacitance and the line parameters.

This aspect of the disclosure is based on measuring voltage values at the beginning of an exponential charging curve only to reduce response time. A logarithm (such as the natural logarithm) of a derivative of these values is calculated and a line is fit through these calculated values. The line has defined parameters (such as slope and y-intercept). The idea underlying this aspect lies in that the parameters of this line are measured and used to calculate the end voltage. Using such regression analysis, the settled in value, (i.e., the end voltage reached at the end of charging the capacitance), may be calculated more quickly without having to wait for the voltage to settle in.

According to an embodiment, the line parameters include a slope m and a y-intercept b, wherein the initial voltage value of the capacitance, the slope m, and the y-intercept b are used to calculate the end voltage. The parameters m and b may be determined from the line.

In this respect, it may be provided, when τ is the time constant of the RC system, the voltage values of the exponential charging curve are measured up to at most t or up to at most τ/2. The response time after switching to a different state is reduced accordingly.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

The disclosure is explained in more detail on the basis of embodiments with reference to the accompanying drawings in which:

FIG. 1 depicts an example of a fault monitoring device for a power system.

FIG. 2 depicts an example of a capacitor charging voltage dependent on time.

FIG. 3 depicts an example of a line fitted through the logarithm of the derivative of voltage values measured at the beginning of a capacitor charging.

FIG. 4 depicts a flow chart of an example of a method for estimating the end voltage reached at the end of charging a capacitance.

### DETAILED DESCRIPTION

Aspects and embodiments of the present disclosure are now discussed with reference to the accompanying figures. Further aspects and embodiments will be apparent to those skilled in the art.

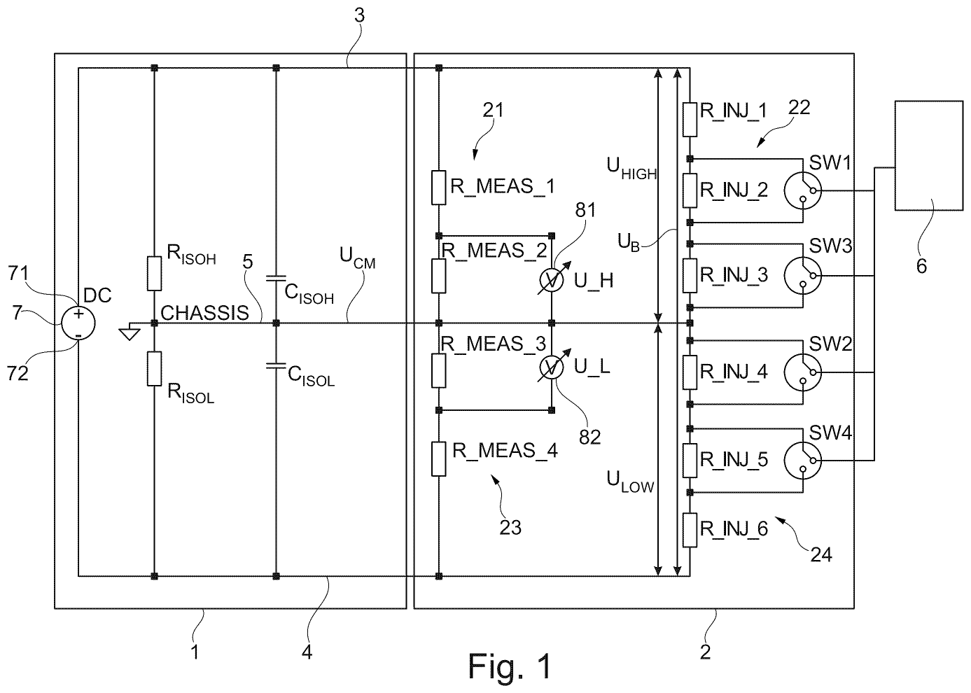

FIG. 1 shows an embodiment of a fault monitoring device 2. The fault monitoring device 2 is configured to measure a high side insulation resistance R_{ISOH} and a low side insulation resistance R_{ISOL} of a power system 1.

The power system 1 is shown on the left-hand side of FIG. 1. It includes a DC battery 7 that has a positive terminal 71 and a negative terminal 72. A battery voltage U_{B} is present between the positive terminal 71 and the negative terminal 72. A high side voltage rail 3 is connected to the DC battery positive terminal 71 and a low side voltage rail 4 is connected to the DC battery negative terminal 72. The high side voltage rail 3 and the low side voltage rail 4 form a high-voltage bus.

The power system 1 further includes a chassis 5. The chassis 5 is insulated from the high side voltage rail 3 by the high side insulation resistance R_{ISOH}. Further, the chassis 5 is insulated from the low side voltage rail 4 by the low side insulation resistance R_{ISOL}.

The voltage between the high side voltage rail 3 and the chassis 5 is the high side voltage U_{HIGH}. The voltage between the chassis 5 and the low side voltage rail 4 is the low voltage U_{LOW}. The sum of the high voltage and the low voltage is equal to the battery voltage: U_{B}=U_{HIGH}+U_{LOW}. A common mode voltage U_{CM} is present at the chassis 5, the common mode voltage being defined as the arithmetic mean of the high voltage and the low voltage: U_{CM}=½(U_{HIGH}−U_{LOW}). If the high voltage U_{HIGH} and the low voltage U_{LOW} are equal, the common mode voltage is zero.

In parallel to the high side insulation resistance R_{ISOH}, a capacitance C_{ISOH} is arranged between the chassis 5 and the high side voltage rail 3. Similarly, in parallel to the low side insulation resistance R_{ISOL}, a capacitance C_{ISOL} is arranged between the chassis 5 and the low side voltage rail 4. The capacitances C_{ISOH} and C_{ISOL} represent capacitive loads of the system.

In a power system such as the power system 1 of FIG. 1, it is required that the insulation of the high side voltage rail 3 and of the low side voltage rail 4 from the chassis 5 is monitored. This may be done by monitoring the values of the resistances R_{ISOH} and R_{ISOL}. The fault monitoring device 2 of FIG. 1 serves to provide for such monitoring.

The fault monitoring device 2 includes a first parallel circuit of resistors, the first parallel circuit including a first branch 21 and a second branch 23 that are both connected at one end thereof to the high side voltage rail 3 of the power system 1. The first branch 21 includes a first resistor M_MEAS_1 and a second resistor M_MEAS_2 arranged in series and form a first voltage divider. The resistance of the first resistor M_MEAS_1 is larger than the resistance of the second resistor M_MEAS_2. For example, the first resistor M_MEAS_1 may have a resistance in the range of 10 MΩ to 50 MΩ, while the second resistor M_MEAS_2 may have a resistance in the range of 10 kΩ to 100 kΩ.

A voltage U_H is measured by a first voltage meter 81 between a point between the first and second resistors M_MEAS_1, M_MEAS_2 and the chassis 5. By measuring the voltage U_H, the high voltage U_{HIGH} may be calculated using the formula:

$${U}_{HIGH} = \frac{{R}_{{MEAS}_{1}} + {R}_{{MEAS}_{2}}}{{R}_{{MEAS}_{2}}} {U}_{H}$$

The second branch 22 of the first parallel circuit includes three electrical resistors R_INJ_1, R_INJ_2, R_INJ_3 arranged in series, wherein two of the electrical resistors R_INJ_2, R_INJ_3 may be short-circuited by a first switch SW1 and a third switch SW3.

The fault monitoring device 2 further includes a second parallel circuit of resistors, the second parallel circuit including a third branch 23 and a fourth branch 24 that are both connected at one end thereof to the low side voltage rail 4 of the power system 1. The third branch 21 includes a third resistor M_MEAS_3 and a fourth resistor M_MEAS_4 arranged in series and form a second voltage divider. The resistance of the fourth resistor M_MEAS_4 is larger than the resistance of the third resistor M_MEAS_3. For example, the fourth resistor M_MEAS_4 may have a resistance in the range of 10 MΩ to 50 MΩ, while the third resistor M_MEAS_3 may have a resistance in the range of 10 kΩ to 100 kΩ.

A voltage U_L is measured by a second voltage meter 82 between a point between the third and fourth resistors M_MEAS_3, M_MEAS_4 and the chassis 5. By measuring the voltage U_L, the low voltage U_{LOW} may be calculated using the formula:

$${U}_{LOW} = \frac{R\_MEAS \_ 3 + R\_MEAS \_ 4}{R\_MEAS \_ 3} U\_L$$

The voltage dividers of branches 21, 23 thus serve to measure the high voltage U_{HIGH} and the low voltage U_{LOW}. Other embodiments may use other methods to get or measure or determine U_HIGH and U_LOW.

The fourth branch 24 of the second parallel circuit includes three electrical resistors R_INJ_4, R_INJ_5, R_INJ_6 arranged in series, wherein two of the electrical resistors R_INJ_4, R_INJ_5 may be short-circuited by a second switch SW2 and a fourth switch SW4.

The first branch 21, the second branch 22, the third branch 23 and the fourth branch 24 are each connected at the other end thereof to the chassis 5 of the power system 1.

When applying the fault monitoring device 2 to the power system 1, the first parallel circuit 21, 22 with branches 21, 22 is connected in parallel to the high side insulation resistance R_{ISOH} and the second parallel circuit 23, 24 with branches 23, 24 is connected in parallel to the low side insulation resistance R_{ISOL}. By switching the switches SW1 to SW4, a common mode voltage V_{CM} different from zero may be injected.

The fault monitoring device 2 further includes a controller 6 schematically depicted in FIG. 1. The controller 6 may be implemented in software and/or hardware. For example, the controller 6 may include software stored in a memory and executed by a processor. The controller 6 is operatively coupled to the switches SW1, SW2, SW3, SW4 and configured to selectively switch the switches SW1, SW2, SW3, SW4 of the second branch 22 and of the fourth branch 24, thereby providing for different states of the first and second parallel circuits 21, 22, 23, 24. The controller 6 is further configured to determine from voltage changes associated with the different states the resistance values for the high side insulation resistance R_{ISOH} and for the low side insulation resistance R_{ISOL} of the power system 1. In this respect, the controller 6 may control and/or read values of other elements of the fault monitoring device 2 as well such as of voltage meters 81, 82 measuring the voltages U_H, U_L.

Accordingly, by selectively switching different of the switches SW1, SW2, SW3, SW4, voltage changes may be induced which lead to different common mode voltages that are impressed on the high-voltage bus, wherein the different voltages are associated with different states, and wherein the different states are defined by the selective switching of the switches SW1, SW2, SW3, SW4.

This will in the following be discussed in an embodiment, wherein two states that corresponds with two different selective switchings are considered and evaluated to determine the value of the resistances R_{ISOH} and R_{ISOL}. In other embodiments, however, other of the switches SW1, SW2, SW3, SW4 may be selected, achieving a similar result. Also, it may be provided for in alternative embodiments that only one switch or more than two switches are arranged in branches 22, 24. Accordingly, the following embodiment is to be understood as an example only.

With the embodiment of FIG. 1 having two switches in each branch 22, 24, two measurement ranges may be implemented alternatively. The two measurement ranges are applied depending on the value of the resistances R_{ISOH} and R_{ISOL}. More particularly, a high measurement range is defined when (R_{ISOH}*R_{ISOL})/(R_{ISOH}+R_{ISOL}) is large in value, such as larger than a particular resistance value dependent on system parameters such as 2MΩ.

A low measurement range is defined when (R_{ISOH}*R_{ISOL})/(R_{ISOH}+R_{ISOL}) is small in value, such as smaller than a particular resistance value dependent on system parameters such as 2MΩ.

In the high measurement range, switches SW1 and SW2 are used. In the low measurement range, switches SW3 and SW4 are used.

Two states, state 1 and state 2, of the resistor circuits (and thus the fault monitoring device) are defined as follows.

In state 1, one of the switches SW1, SW3 on the high side branch 22 is closed (meaning SW1 or SW3 is ON and the respective resistor R_INJ_2, R_INJ_3 is short-circuited), while on the low side branch 24 every switch is open (SW2 and SW4 are OFF, meaning none of the resistors R_INJ_4, R_INJ_5) are short-circuited). Switch SW1 is ON in the high measurement range. Switch SW3 is ON in the low measurement range.

In state 2, one the switches SW2, SW4 on the low side branch 24 is closed (meaning SW2 or SW4 is ON and the respective resistor R_INJ_4, R_INJ_5 is short-circuited), while on the high side branch 22 every switch is open (SW1 and SW3 are OFF, meaning none of the resistors R_INJ_2, R_INJ_3 are short-circuited). Switch SW2 is ON in the high measurement range. Switch SW4 is ON in the low measurement range.

Further, the following assumptions are made, and abbreviations are introduced, such that the subsequent equations become simpler:

$${R}_{MEAS} = R\_MEAS \_ 1 + R\_MEAS \_ 2 = R\_MEAS \_ 3 + R\_MEAS \_ 4$$

$${R}_{{INJ}_{OFF}} = R\_INJ \_ 1 + R\_INJ \_ 2 + R\_INJ \_ 3 = R\_INJ \_ 4 + R\_INJ \_ 5 + R\_INJ \_ 6$$

For the high measurement range: R_{INJON}=R_INJ_1+R_INJ_3=R_INJ_5+R_INJ_6

For the low measurement range: R_{INJON}=R_INJ_1+R_INJ_2=R_INJ_4+R_INJ_6

U_{HIGH}_{₁}: U_{HIGH} measured in state 1

U_{HIGH}_{₂}: U_{HIGH} measured in state 2

U_{LOW}_{₁}: U_{LOW} measured in state 1

U_{LOW} _{₂}: U_{LOW} measured in state 2

Accordingly, it is assumed that the high-voltage side and the low-voltage side are symmetrical. These assumptions are not necessary though, and the skilled person will appreciate that they are not required. For example, every resistor may be different.

Further, the total resistance R_{H} is defined as the total resistance between the chassis 5 and the high side voltage rail 3. The total resistance R_{H} depends on the resistance R_{ISOH} of the power system 1 and of the resistances of the branches 21, 22 of the fault monitoring device 2, wherein in accordance with the laws on parallel resistors the total resistance R_{H} of all branches is the reciprocal of the sum of the reciprocals of the resistances of each branch (with the resistance R_{ISOH} also representing one branch).

R_{H1} is the total resistance R_{H} in the first state and R_{H2} is the total resistance R_{H} in the second state.

Further, the total resistance R_{L} is defined as the total resistance between the chassis 5 and the low side voltage rail 4. The total resistance R_{L} depends on the resistance R_{ISOL} of the power system 1 and of the resistances of the branches 23, 24 of the fault monitoring device 2, wherein in accordance with the laws on parallel resistors the total resistance R_{L} of all branches is the reciprocal of the sum of the reciprocals of the resistances of each branch (with the resistance R_{ISOL} also representing one branch).

R_{L1} is the total resistance R_{L} in the first state and R_{L2} is the total resistance R_{L} in the second state.

Based on the above definitions and values, the following is true under Ohm's law:

$$\frac{{R}_{H}}{{R}_{L}} = \frac{{U}_{HIGH}}{{U}_{LOW}}$$

In state 1, there is a parallel connection of resistances on the high side and low side as follows:

$$\frac{{U}_{{HIGH}_{1}}}{{U}_{{LOW}_{1}}} = \frac{{R}_{{H}_{1}}}{{R}_{{L}_{1}}} = \frac{\frac{1}{\frac{1}{{R}_{{ISO}_{H}}} + \frac{1}{{R}_{MEAS}} + \frac{1}{{R}_{{INJ}_{ON}}}}}{\frac{1}{\frac{1}{{R}_{{ISO}_{L}}} + \frac{1}{{R}_{MEAS}} + \frac{1}{{R}_{{INJ}_{OFF}}}}} = \frac{\frac{1}{{R}_{{ISO}_{L}}} + \frac{1}{{R}_{MEAS}} + \frac{1}{{R}_{{INJ}_{OFF}}}}{\frac{1}{{R}_{{ISO}_{H}}} + \frac{1}{{R}_{MEAS}} + \frac{1}{{R}_{{INJ}_{ON}}}}$$

In state 2, there is a parallel connection of resistances on the high side and low side as follows:

$$\frac{{U}_{{HIGH}_{2}}}{{U}_{{LOW}_{2}}} = \frac{{R}_{{H}_{2}}}{{R}_{{L}_{2}}} = \frac{\frac{1}{\frac{1}{{R}_{{ISO}_{H}}} + \frac{1}{{R}_{MEAS}} + \frac{1}{{R}_{{INJ}_{OFF}}}}}{\frac{1}{\frac{1}{{R}_{{ISO}_{L}}} + \frac{1}{{R}_{MEAS}} + \frac{1}{{R}_{{INJ}_{ON}}}}} = \frac{\frac{1}{{R}_{{ISO}_{L}}} + \frac{1}{{R}_{MEAS}} + \frac{1}{{R}_{{INJ}_{ON}}}}{\frac{1}{{R}_{{ISO}_{H}}} + \frac{1}{{R}_{MEAS}} + \frac{1}{{R}_{{INJ}_{OFF}}}}$$

The only two unknowns in these equations are R_{ISO}_{_{H}} and R_{ISO}_{_{L}}. These may be expressed as follows:

$${R}_{{ISO}_{H}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}- \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \\ \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}} + \frac{1}{{R}_{{INJ}_{OFF}}} - \frac{1}{{R}_{{INJ}_{ON}}}\end{matrix}}$$

$${R}_{{ISO}_{L}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}\frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{OFF}}} - \frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{ON}}} - \\ \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}}\end{matrix}}$$

Accordingly, R_{ISOH} and R_{ISOL} may be monitored by the fault monitoring device 2 by introducing different states by the switches SW1, SW2, SW3, SW4, by measuring the above stated voltage and resistance values, by carrying out the above calculations for R_{ISOH} and R_{ISOL}. Different states may be defined for a high measurement range and for low measurement range.

The measurements and calculations may be carried out by the controller 6 or an entity connected to controller 6 (which also would be a controlling entity).

As already pointed out, this calculation is to be understood as an example only. In other embodiments, different switching of switches SW1, SW2, SW3, SW4 may be implemented. For example, alternatively, switches SW1 and SW3 may be switched together and switches SW2 and SW4 may be switched together to achieve additional measurement ranges. Further, the above stated assumptions are not required. For example, all resistors may have different values. The above formulae then turn more complex but are still based on well-known principles about the total resistance in parallel circuits and series circuits.

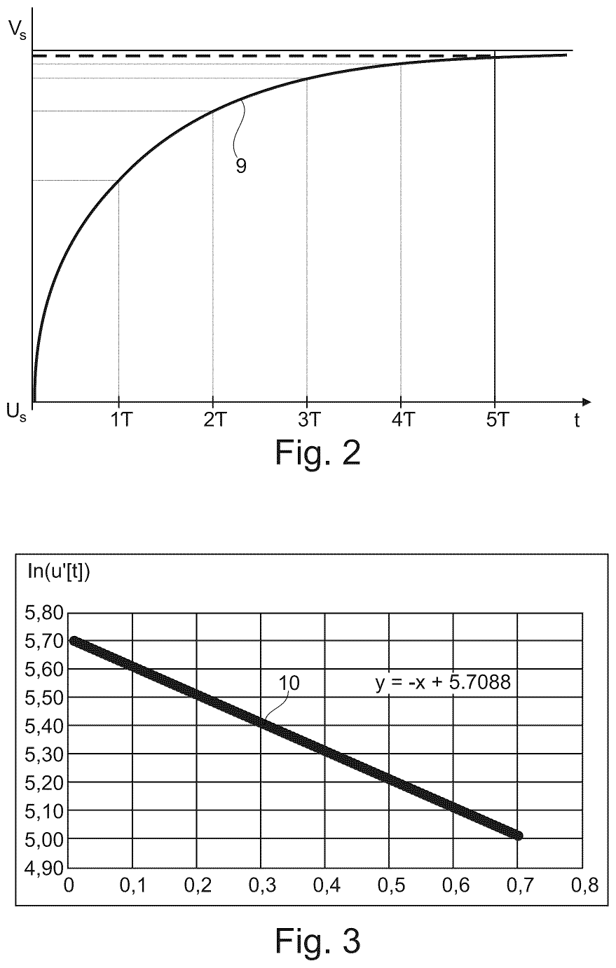

The described fault monitoring device 2 may be further improved by implementing a method for estimating the end voltage reached at the end of charging the capacitances C_ISO_H and C_ISO_H. A problem is based on the fact that, upon a voltage change caused by the selective switching, the capacitances C_ISO_H and C_ISO_H are charged. As is well known, in such case, the voltage settles with an exponential curve, the exponential curve having a time constant τ which depends on the product of resistance and capacitance. This is shown in FIG. 2, which schematically depicts the well-known curve 9 for charging a capacitor, wherein the voltage is shown dependent on time, wherein the x-axis is divided in multiples of the time constant τ. It may be assumed that after at least five times the time constant τ the voltage is settled in. When making the measurements discussed with respect to FIG. 1 after the voltage has settled in (to have the correct values of, e.g., U_{HIGH} and U_{LOW}), a long response time of, e.g., up to 20-200 seconds, is present when a high capacitance and a high resistance are present on the high-voltage bus.

To avoid such a long response times, aspects of the present disclosure implement a regression analysis which estimates the changed voltages before they are settled in. In particular, and exponential regression calculation method is implemented.

The exponential regression calculation method is based on the following considerations.

The capacitor charging equation in an RC circuit with an initial U₁ voltage charged up to a U₂ voltage, and with a time constant τ reads:

$$U ( t ) = ( {U}_{1} - {U}_{2} ) \cdot {e}^{- \frac{t}{τ}} + {U}_{2}$$

U₂ is the end voltage of interest.

The derivative by time is:

$${U}^{′} ( t ) = \frac{dU ( t )}{dt} = ( {U}_{1} - {U}_{2} ) \cdot {e}^{- \frac{t}{τ}} \cdot - \frac{1}{τ} = ( {U}_{2} - {U}_{1} ) \cdot {e}^{- \frac{t}{τ}} \cdot \frac{1}{τ}$$

Next, the natural logarithm of both sides is taken, this leading to a linear equation as follows:

$$ln ( {U}^{′} ( t ) ) = ln ( ( {U}_{2} - {U}_{1} ) \cdot {e}^{- \frac{t}{τ}} \cdot \frac{1}{τ} ) = ln ( ( {U}_{2} - {U}_{1} ) \cdot \frac{1}{τ} ) + ln ( {e}^{- \frac{t}{τ}} ) = ln ( ( {U}_{2} - {U}_{1} ) \cdot \frac{1}{τ} ) - \frac{t}{τ}$$

This aspect is based on the realization that the above equation is similar to the well-known equation of a line:

$$f ( t ) = mt + b ,$$

wherein m is the slope and b is the y-intercept.

Comparing the ln(U′(t)) with f(t) leads to:

$$m = - \frac{1}{τ} ; b = ln ( ( {U}_{2} - {U}_{1} ) \cdot \frac{1}{τ} )$$

The variable of interest is U₂. U₁ as the initial voltage is known. The parameters m and b may be calculated, τ is unknown. The above formula may be transformed to:

$$τ = - \frac{1}{m} ; {e}^{b} = ( {U}_{2} - {U}_{1} ) \cdot \frac{1}{τ}$$

$${e}^{b} = ( {U}_{2} - {U}_{1} ) \cdot - m$$

$${U}_{2} = {U}_{1} - \frac{{e}^{b}}{m}$$

What is still required is to determine the parameters m and b.

To this end, the measured voltage values at the beginning of the exponential charging curve 9 of FIG. 2 are measured and further analyzed. It is only the voltage values at the beginning of the charging curve 9 that are measured and further analyzed as, otherwise, the response time would not be reduced. For example, only the voltage values within the first time interval between 0 and 1τ or the first half of that time interval (τ/2) are considered.

The voltage values u(t) are measured at discrete time intervals: u[tₙ].

The derivative may be found by:

$${u}^{′} [ {t}_{n} ] = \frac{u [ {t}_{n} ] - u [ {t}_{n - 1} ]}{{t}_{n} - {t}_{n - 1}} .$$

The natural logarithm of u′[tₙ] is:

$$ln ( {u}^{′} [ {t}_{n} ] ) = ln ( \frac{u [ {t}_{n} ] - u [ {t}_{n - 1} ]}{{t}_{n} - {t}_{n - 1}} )$$

The natural logarithm leads to a sequence of discrete points approximately forming a line. For these points a simple linear regression may be implemented to get the m and b values. This is illustrated in FIG. 3, which shows ln(u′[tₙ]) dependent on time, wherein the time resolution is 0.1 seconds. After linear regression, a line 10 is present and the m and b values may thus be taken from the determined line 10. In the embodiment shown in FIG. 3, m is equal to −1 and b is equal to 5.7088.

This allows to determine a U₂ according to the formula:

$${U}_{2} = {U}_{1} - \frac{{e}^{b}}{m}$$

The regression calculation thus allows to determine the end voltage U₂ in much less time compared an exponential setting of the voltage.

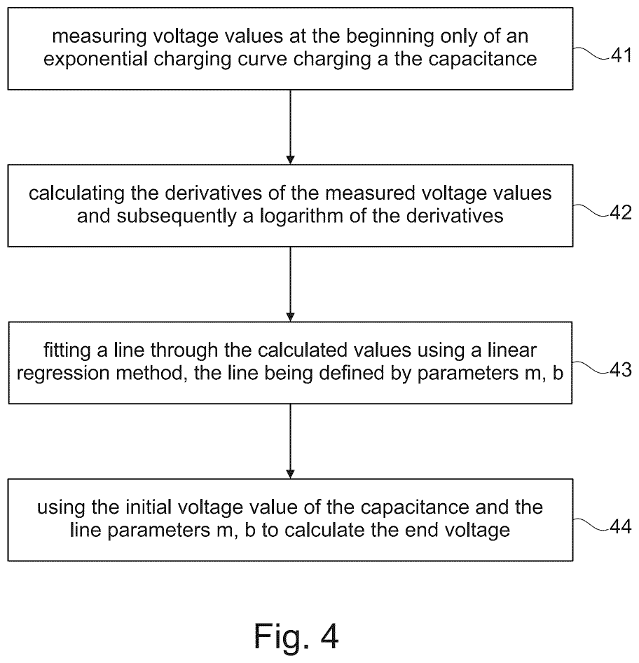

FIG. 4 summarizes various acts of the method. In act 41, the voltage values at the beginning of an exponential charging curve charging a capacitance are measured, such as the voltage values within a time interval of τ or τ/2.

In act 42, the derivatives of the measured voltage values are calculated and subsequently a logarithm of the derivatives is taken. This leads to a sequence of values which is arranged approximately as a line.

In act 43, a line is fitted through the calculated values using a linear regression method. The fitted line naturally is defined by parameters such as parameters m, b (other representations of a line may use different parameters).

In act 44, the initial voltage value of the capacitance and the line parameters m, b are used to calculate the end voltage U₂, e.g., in accordance with the above formula.

It should be understood that the above description is intended for illustrative purposes only and is not intended to limit the scope of the present disclosure in any way. Also, those skilled in the art will appreciate that other aspects of the disclosure may be obtained from a study of the drawings, the disclosure and the appended claims. All methods described herein may be performed in any suitable order unless otherwise indicated herein or otherwise clearly contradicted by context. Various features of the various embodiments disclosed herein may be combined in different combinations to create new embodiments within the scope of the present disclosure. In particular, the disclosure extends to and includes all combinations and sub-combinations of one or more features described herein. Any ranges given herein include any and all specific values within the range and any and all sub-ranges within the given range.

1. A fault monitoring device for a power system that comprises a high side voltage rail, a low side voltage rail, and a chassis insulated by a high side insulation resistance from the high side voltage rail and insulated by a low side insulation resistance from the low side voltage rail, the fault monitoring device comprising:
a controller;
a first parallel circuit of resistors, the first parallel circuit comprising a first branch and a second branch, wherein both the first branch and the second branch are connected at one respective end thereof to the high side voltage rail of the power system; and
a second parallel circuit of resistors, the second parallel circuit comprising a third branch and a fourth branch, wherein both the third branch and the fourth branch are connected at one respective end thereof to the low side voltage rail of the power system,
wherein the first branch, the second branch, the third branch, and the fourth branch are each connected at the other respective end thereof to the chassis of the power system,
wherein the second branch of the first parallel circuit comprises at least two electrical resistors arranged in series, wherein at least one electrical resistor of the electrical resistors is configured to be short-circuited by a first switch,
wherein the fourth branch of the second parallel circuit comprises at least two electrical resistors arranged in series, wherein at least one of the electrical resistors may be short-circuited by a second switch,
wherein the controller is configured to selectively switch the first switch of the second branch and the second switch of the fourth branch to provide for different states of the first parallel circuit and the second parallel circuit, and
wherein the controller is further configured to determine resistance values for the high side insulation resistance and for the low side insulation resistance of the power system from voltage changes associated with the different states.

2. The fault monitoring device of claim 1, wherein the second branch of the first parallel circuit comprises three electrical resistors arranged in series, and
wherein two electrical resistors of the three electrical resistors are configured to be short-circuited by the first switch and a third switch, respectively.

3. The fault monitoring device of claim 2, wherein the fourth branch of the second parallel circuit comprises three electrical resistors arranged in series, and
wherein two electrical resistors of the three electrical resistors are configured to be short-circuited by the second switch and a fourth switch, respectively.

4. The fault monitoring device of claim 1, wherein the controller is configured to define two different states by the selective switching, and
wherein the controller determines the resistance values for the high side insulation resistance and the low side insulation resistance from the voltage changes associated with the two different states.

5. The fault monitoring device of claim 4, wherein the controller is configured to determine the resistance values by:
measuring a high side voltage between the high side voltage rail and the chassis;
measuring a low side voltage between the chassis and the low side voltage rail;
measuring the high side voltage and the low side voltage in the two different states; and
calculating the high side insulation resistance and the low side insulation resistance using the high side voltages of the two different states, the low side voltages of the two different states, and a change of resistance of a sum of the resistors of the second branch and/or of a sum of the resistors of the fourth branch between the two different states.

6. The fault monitoring device of claim 5, wherein the first branch comprises a first voltage divider,
wherein the fault monitoring device is configured to measure the high side voltage between the high side voltage rail and the chassis by the first voltage divider,
wherein the third branch comprises a second voltage divider, and
wherein the fault monitoring device is configured to measure the low side voltage between the chassis and the low side voltage rail by the second voltage divider.

7. The fault monitoring device of claim 4, wherein a first state of the two different states is defined in that one electrical resistor of the electrical resistors of the second branch is short-circuited while no electrical resistor of the electrical resistors of the fourth branch is short-circuited, and
wherein a second state of the two different states is defined in that no electrical resistor of the electrical resistors of the second branch is short-circuited while one electrical resistor of the electrical resistors of the fourth branch is short-circuited.

8. The fault monitoring device of claim 7, wherein the fourth branch of the second parallel circuit comprises three electrical resistors arranged in series,
wherein two electrical resistors of the three electrical resistors are configured to be short-circuited by the second switch and a fourth switch, respectively,
wherein, in the first state, one electrical resistor of the electrical resistors of the second branch is short-circuited by the first switch, and
wherein, in the second state, one electrical resistor of the electrical resistors of the fourth branch is short-circuited by the second switch.

9. The fault monitoring device of claim 7, wherein the fourth branch of the second parallel circuit comprises three electrical resistors arranged in series,
wherein two electrical resistors of the three electrical resistors are configured to be short-circuited by the second switch and a fourth switch, respectively,
wherein, in the first state, one electrical resistor of the electrical resistors of the second branch is short-circuited by a third switch, and
wherein, in the second state, one electrical resistor of the electrical resistors of the fourth branch is short-circuited by the fourth switch.

10. The fault monitoring device of claim 7, wherein the high side insulation resistance and the low side insulation resistance are calculated by:
$${R}_{{ISO}_{H}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}- \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \\ \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}} + \frac{1}{{R}_{{INJ}_{OFF}}} - \frac{1}{{R}_{{INJ}_{ON}}}\end{matrix}}$$
$${R}_{{ISO}_{L}} = \frac{\frac{{U}_{{HIGH}_{1}}}{{U}_{{LOW}_{1}}} - \frac{{U}_{{HIGH}_{2}}}{{U}_{{LOW}_{2}}}}{\begin{matrix}\frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{OFF}}} - \frac{{U}_{{HIGH}_{1}}}{{U}_{{LOW}_{1}}} \frac{{U}_{{HIGH}_{2}}}{{U}_{{LOW}_{2}}} \frac{1}{{R}_{{INJ}_{ON}}} - \\ \frac{{U}_{{HIGH}_{1}}}{{U}_{{LOW}_{1}}} \frac{1}{{R}_{MEAS}} - \frac{{U}_{{HIGH}_{1}}}{{U}_{{LOW}_{1}}} \frac{1}{{R}_{{INJ}_{ON}}} + \frac{{U}_{{HIGH}_{2}}}{{U}_{{LOW}_{2}}} \frac{1}{{R}_{MEAS}} + \frac{{U}_{{HIGH}_{2}}}{{U}_{{LOW}_{2}}} \frac{1}{{R}_{{INJ}_{OFF}}}\end{matrix}}$$
wherein:
R_{ISOH} is the high side insulation resistance;
R_{ISOL} is the low side insulation resistance;
U_{HIGH1} is a high side voltage between the high side voltage rail and the chassis in the first state;
U_{HIGH2} is a high side voltage between the high side voltage rail and the chassis in the second state;
U_{LOW1} is a low side voltage between the chassis and the low side voltage rail in the first state;
U_{LOW2} is a low side voltage between the chassis and the low side voltage rail in the second state;
R_{MEAS} is a resistance of the first branch and the resistance of the third branch;
R_{INJON} is a resistance of a sum of the resistors of the second branch and a sum of the resistors of the fourth branch when one of the resistors of the respective branch is short-circuited; and
R_{INJOFF} is a resistance of the sum of the resistors of the second branch and the sum of the resistors of the fourth branch when none of the resistors are short-circuited.

11. The fault monitoring device of claim 1, wherein the voltage changes associated with the different states settle with an exponential curve due to capacitances connected in parallel to the high side insulation resistance and the low side insulation resistance, and
wherein the controller is configured to apply a regression analysis that estimates the voltage changes before the voltage changes are settled in.

12. The fault monitoring device of claim 11, wherein the regression analysis comprises:
measuring voltage values at a beginning only of an exponential charging curve charging a capacitance;
calculating derivatives of the measured voltage values and subsequently a logarithm of the derivatives;
fitting a line through the calculated values using a linear regression method, the line being defined by line parameters; and
calculating an end voltage using an initial voltage value of the capacitance and the line parameters.

13. The fault monitoring device of claim 12, wherein the line parameters comprise a slope and a y-intercept, and
wherein the controller is configured to calculate the end voltage using the initial voltage value of the capacitance, the slope, and the y-intercept.

14. The fault monitoring device of claim 13, wherein, when τ is a time constant of the capacitance, the voltage values of the exponential charging curve are measured up to at most τ or at most τ/2.

15. A power system comprising:
a direct current (DC) battery having a DC battery positive terminal, a DC battery negative terminal, and a battery voltage;
a high side voltage rail connected to the DC battery positive terminal;
a low side voltage rail connected to the DC battery negative terminal;
a chassis;
a high side insulation resistance insulating the chassis from the high side voltage rail;
a low side insulation resistance insulating the chassis from the low side voltage rail; and
a fault monitoring device comprising:
a controller;
a first parallel circuit of resistors, the first parallel circuit comprising a first branch and a second branch, wherein both the first branch and the second branch are connected at one respective end thereof to the high side voltage rail of the power system; and
a second parallel circuit of resistors, the second parallel circuit comprising a third branch and a fourth branch, wherein both the third branch and the fourth branch are connected at one respective end thereof to the low side voltage rail of the power system,
wherein the first branch, the second branch, the third branch, and the fourth branch are each connected at the other respective end thereof to the chassis of the power system,
wherein the second branch of the first parallel circuit comprises at least two electrical resistors arranged in series, wherein at least one electrical resistor of the electrical resistors is configured to be short-circuited by a first switch,
wherein the fourth branch of the second parallel circuit comprises at least two electrical resistors arranged in series, wherein at least one of the electrical resistors may be short-circuited by a second switch,
wherein the controller is configured to selectively switch the first switch of the second branch and the second switch of the fourth branch to provide for different states of the first parallel circuit and the second parallel circuit, and
wherein the controller is further configured to determine resistance values for the high side insulation resistance and for the low side insulation resistance of the power system from voltage changes associated with the different states.

16. A method for estimating an end voltage reached at an end of charging a capacitance, the method comprising:
measuring voltage values at a beginning only of an exponential charging curve charging the capacitance;
calculating derivatives of the measured voltage values and subsequently a logarithm of the derivatives;
fitting a line through the logarithm of the derivatives using a linear regression method, the line being defined by line parameters; and
calculating the end voltage using an initial voltage value of the capacitance and the line parameters.

17. The method of claim 16, wherein the line parameters comprise a slope and a y-intercept, and
wherein the initial voltage value of the capacitance, the slope, and the y-intercept are used to calculate the end voltage.

18. The method of claim 16, wherein, when τ is a charging time of the capacitance in an RC system, the voltage values of the exponential charging curve are measured up to at most τ or at most τ/2.
